(19) United States
(12) Patent Application Publication
(10) Pub. No.: US 2003/0152180 A1
(43) Pub. Date: Aug. 14, 2003

(54) Method and device for controlling the timing of a digital receiver

(76) Inventor: Heinrich Schenk, Munich (DE)

Correspondence Address: NUTTER MCCLENNEN & FISH LLP, WORLD TRADE CENTER WEST, 155 SEAPORT BOULEVARD, BOSTON, MA, 02210-2604, US

(21) Appl. No.: 10/296,118

(22) PCT Filed: May 15, 2001
(86) PCT No.: PCT/EP01/05518

(30) Foreign Application Priority Data
May 24, 2000 (DE) 100 25 566.3

(51) Int. Cl. H04L 7/00; H03H 7/40; H03H 7/30; H03K 5/159; H04B 1/10

(52) U.S. Cl. 375/355; 375/232; 375/350

(57) ABSTRACT

For controlling the sampling timing of a digital data receiver (2) with the aid of a timing control loop (3-6), it is proposed that the timing control criterion (Trk) for the timing control loop is obtained by combining a first portion (Trk1) with a second portion (Trk2). The first portion (Trk1) of the timing control criterion is obtained by evaluating the input and output signals of the decision element (8) of the digital receiver (2), while the second portion (Trk) is obtained by evaluating at least one coefficient (C₋₁) of the adaptive equaliser (7) of the digital receiver (2). In this way, favourable jitter characteristics and also a stable control response are achieved.

The present invention relates to a method for controlling the sampling timing or sampling clock of a digital receiver according to the preamble of claim 1 as well as a corresponding device according to the preamble of claim 10.

The use of a digital timing control loop for controlling the sampling timing of a digital receiver is known. A corresponding simplified block circuit diagram is shown in FIG. 4.

As shown in FIG. 4, an input signal is fed to a digital data receiver 2 via an analogue/digital converter 1 (A/D-converter). The digital data receiver 2 comprises an input filter, an adaptive equaliser as well as a decision element, to define or decide the symbol values of the input signal and to emit these as received data for further processing. The sampling timing f_{T} of the A/D-converter 1 is obtained with the aid of a digital timing control loop, which, like a conventional analogue phase locked loop (PLL), comprises a device 3 for determining the phase error or a corresponding timing control criterion, a loop filter 4 and a device 5 for producing the controlled sampling timing f_{T} in dependence on the output signal of the loop filter 4, that is to say in dependence on the timing control criterion. In an analogue phase control loop, the device 3 is normally formed by a so-called phase discriminator and the device 5 by a voltage controlled oscillator (VCO).

Instead of producing a directly controlled sampling timing, the digital sampling values can also be calculated with a A/D-converter working with an unsolicited sampling timing with the aid of an interpolation unit. A corresponding block circuit diagram is shown in FIG. 5. The A/D-converter 1 shown in FIG. 5 is operated with an unsolicited, that is to say uncontrolled, sampling timing f_{T}. The digital output signal of the A/D-converter 1 is fed via an interpolation unit 6 to the digital data receiver 2. The interpolation unit 6 is controlled on its part by the output signal of the device 5, which, in dependence on the timing control criterion obtained by the device 3, calculates an ideal sampling phase and feeds this to the interpolation unit 6 so that the interpolation unit 6 interpolates the digital sampling values asynchronous present from the A/D-converter 1 into corresponding synchronous sampling values.

Both for the timing control variant shown in FIG. 4 as well as for the timing control variant shown in FIG. 5, the calculation of an appropriate timing control criterion is of central importance. In each case, the timing control criterion produced by the device 3 must be a quantity for the phase error between the ideal sampling timing and the actual sampling timing, whereby the timing control criterion—possibly after appropriate prior processing—is calculated from the particular input signal.

With the calculation of the timing control criterion, in principle, a distinction is made between non-decision regenerative timing control criteria and decision regenerative timing control criteria. To calculate non-decision regenerative timing control criteria, the transmitted symbol values (so-called decision element values) estimated in the particular digital receiver are used. To calculate decision regenerative timing control criteria, on the other hand, the transmitted symbol values estimated in the digital receiver are used. In general, with a decision regenerative control loop, better characteristics regarding the phase jitter occurring in each case are achieved.

The present invention relates to the case of a decision regenerative timing control.

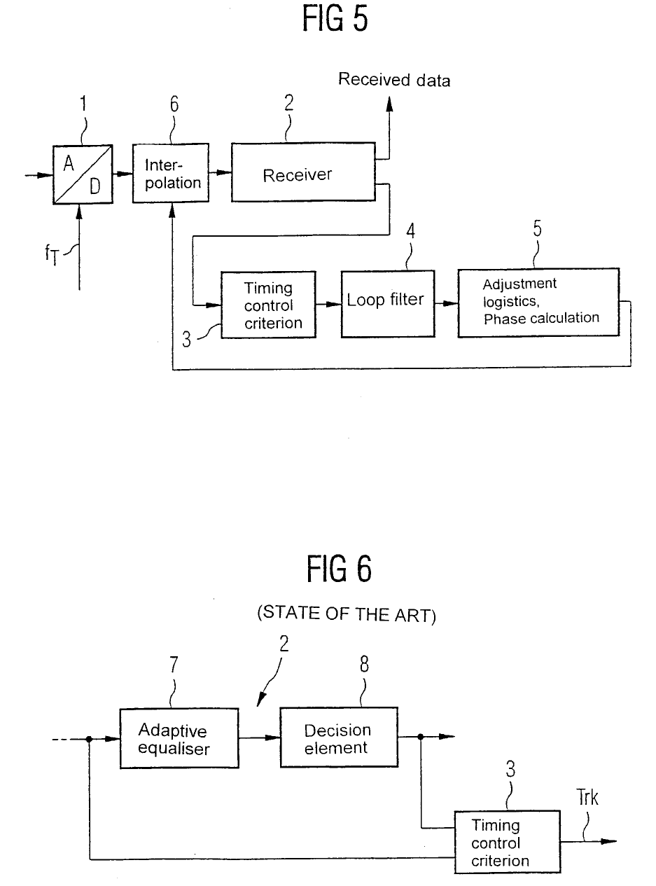

In literature, for example, in Müller, K. H.; Müller, M.: “Timing Recovering Digital Synchronous Data Receivers”, IEEE Transactions on Communications, Vol. COM-24, No. 5, May 1976, Pages 516-531, a basic way to calculate an appropriate timing control criterion is described, in contrast to which the method described in this patent specification can only be used, however, in a receiver arrangement with an adaptive equaliser, when, for generating the timing control criterion, not the signal values directly before the decision element, but the signal values before the equaliser are used. A corresponding arrangement is shown in FIG. 6. In FIG. 6 the adaptive equaliser 7 and the decision element 8 connected after the adaptive equaliser of the digital receiver 2 is shown. The adaptive equaliser 7 serves to equalise the input signal, whereby the coefficients of the adaptive equaliser 7 are variable. The decision element 8 decides, that is to say determines, the individual values of the output symbols received. In the case of the arrangement shown in FIG. 6, the timing control criterion Trk is obtained with the aid of a decision regenerative timing control loop, whereby the device 3 determines the timing control criterion Trk in particular in dependence on the input signal values of the adaptive equaliser 7.

The timing control criterion Trk determined with the arrangement shown in FIG. 6 has a large scatter, since, for generating the timing control criterion Trk, the distorted input signal is used. This again leads to large phase jitter. If the timing control criterion Trk had been derived from the output signal of the adaptive equaliser 7, the timing control criterion Trk would have had less scatter. This method of operation is, however, problematic in so far as coupling with the adaptive equaliser 7 and therefore an unstable response would result.

To solve this problem, it is proposed in Gysel, P.; Gilg, D.: “Timing Recovery in High Bit-Rate Transmission Systems Over Copper Pairs”, IEEE Transactions on Communications, Vol. 46, No. 12, December 1998, Pages 1583-1586, during the adjustment phase of the digital receiver 2, to use the input signal of the adaptive equaliser 7 for generating the timing control criterion, whereby, after the digital receiver for generating the timing control criterion has started, a switch over is made onto the signal after the adaptive equaliser. At the same time, the adjustment of the adaptive equaliser is frozen, i.e. stopped. In this way, on the one hand, less scatter of the timing control criterion is achieved and on the other hand, the connection with the adaptive equaliser no longer applies.

In the case of the method described above, however, it is a disadvantage that the adjustment of the adaptive equaliser after the adjustment phase of the digital receiver is frozen, so that the adaptive equaliser cannot be readjusted later in the event of changes in the channel characteristics which could be caused for example by temperature fluctuations.

The present invention is therefore based on the objective of proposing a method for controlling the sampling timing of a digital receiver as well as a corresponding device with which the problems described above can be solved and, in particular, a timing control criterion can be obtained with minimum scatter and, in addition, with a stable control response.

This objective is achieved by a method with the features of claim 1 or a device with the features of claim 10. The sub-claims in each case define preferred and advantageous embodiments of the present invention.

According to the invention for generating the timing control criterion, a first portion is obtained from the input signal and the output signal of the decision element. For de-coupling the adaptive equaliser, a second portion is additionally generated which is obtained from one or several equaliser coefficients and combined with, and in particular, added to, the first portion. This is possible, since the coefficient values of the equaliser of the digital receiver being adjusted are dependent on the sampling phase. In this way, on the one hand, a timing control criterion with minimum scatter is obtained, which therefore leads to favourable jitter characteristics. On the other hand, through the de-coupling from the adaptive equaliser described above, a stable control response is ensured.

In most applications, it is sufficient to obtain the second portion of the timing control criterion, that is to say the de-coupling or correction quantity from only one or maximum two coefficients of the adaptive equaliser. In particular, the coefficient before the main coefficient and the coefficient after the main coefficient are particularly heavily dependent on the sampling phase, so that it is expedient to use only these two coefficients or only one of these two coefficients for generating the de-coupling quantity.

The first portion of the timing control criterion can, in particular, be obtained from the decision element error, that is to say from the difference between the input and output values of the decision element. In particular, this first portion Trk1(k) of the timing control criterion can be obtained according to the following equation:

Trk1(k)=66 y(k)×a(k−1)−Δy(k−1)×a(k)

In this case, k designates the symbol or sampling time-point, Δy the decision element error, that is to say the difference between the input and output value of the decision element, and a the symbol value decided by the decision element. Alternatively, only the algebraic signs of Δy and a can also be evaluated.

The invention described above can generally be used for controlling the sampling timing of digital data receivers however configured. In particular, the invention can be used both for PAM (pulse amplitude-modulation)—as well as for CAP/QAM (carrier-less amplitude modulation/quadrature amplitude modulation) transmission systems.

The present invention is described in detail below with reference to the attached drawing on the basis of a preferred embodiment.

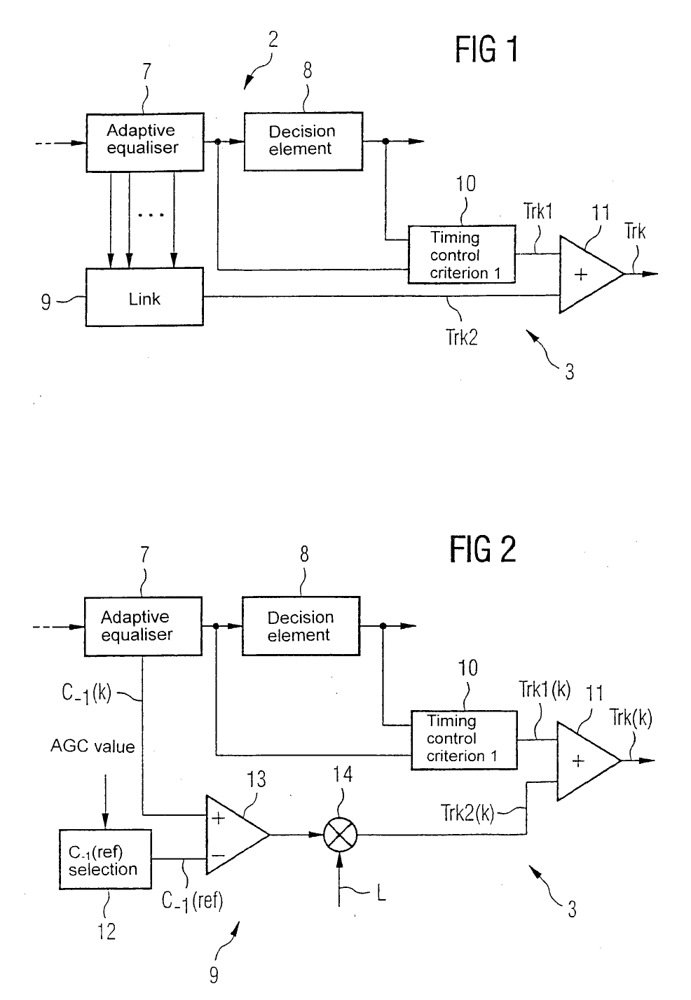

FIG. 1 shows the basic structure of a device according to the invention for obtaining a timing control criterion according to a preferred embodiment.

FIG. 2 shows a detailed illustration of the device shown in FIG. 1 for a PAM transmission system.

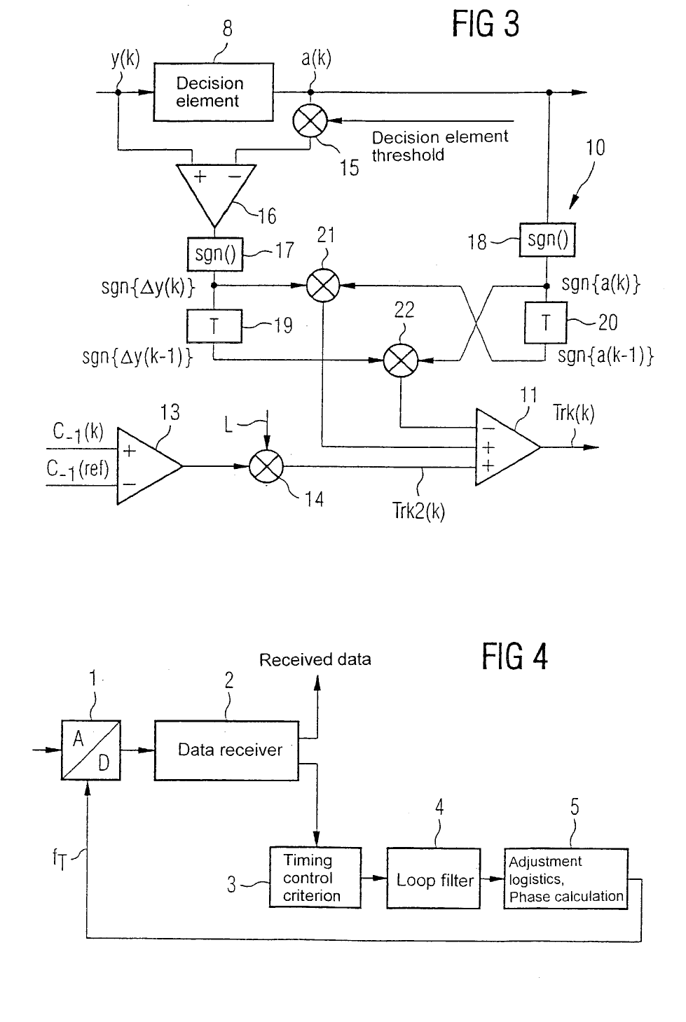

FIG. 3 again shows a detailed illustration of the device shown in FIG. 1 and FIG. 2 for a PAM-transmission system.

FIG. 4 shows the basic structure of a digital timing control loop for a digital receiver.

FIG. 5 shows the basic structure of a digital timing control loop for a digital receiver with digital interpolation and unsolicited sampling timing, and

FIG. 6 shows a device for obtaining a decision regenerative timing control criterion according to the state of the art.

The present invention relates essentially to the type and way in which the timing control criterion necessary for controlling the sampling timing is obtained. For the invention, however, it is immaterial how in fact the sampling timing in dependence on this timing control criterion is controlled. In particular, the present invention can be used for the variant shown in FIG. 4 of direct control of the sampling timing f_{T} as well as for the variant shown in FIG. 5 in which case sampling is carried out with an unsolicited sampling timing f_{T} and the asynchronous digital sampling values obtained in this way are then interpolated.

FIG. 1 shows the basic structure of a device according to the invention for obtaining a timing control criterion Trk.

In this case, a first portion Trk1 of the timing control criterion of a device 10 is obtained from the signal directly before the decision element 8, that is to say after the adaptive equaliser 7, and the signal after the decision element 8. Since, therefore, the signal after the adaptive equaliser 7 is evaluated for obtaining the timing control criterion, less scatter of the timing control criterion can be achieved. Since, however, without additional arrangements in the case of this method of operation, coupling with the adaptive equaliser 7 and therefore an unstable response would arise, for de-coupling the adaptive equaliser 7 from a device 9 a second portion Trk2 of the timing control criterion is generated and added by an adder 11 to the portion Trk1. The total value Trk=Trk1+Trk2 obtained in this way by the adder 11 then becomes the basis of the timing control and according to FIG. 4 or FIG. 5 is fed to the loop filter 4.

The second portion Trk2 of the timing control criterion can therefore be considered as correction or de-coupling quantity for the portion Trk1, which is obtained from the input signal and output signal of the decision element 8. This de-coupling quantity Trk2 is obtained from the device 9 by evaluating one or several coefficients of the adaptive equaliser 7. This is possible since the coefficient values of the adaptive equaliser 7 being adjusted in each case are dependent on the sampling phase. As a result of the de-coupling from the adaptive equaliser 7 brought about in this way, stable timing control characteristics can be achieved.

For most applications, it is sufficient if the de-coupling quantity Trk2 is obtained from only one or maximum two coefficients of the adaptive equaliser 7. Since the coefficient before the main coefficient and the coefficient after the main coefficient of the adaptive equaliser 7 are especially heavily dependent on the sampling phase, it is expedient to use only these two coefficients or only one of these two coefficients for generating the de-coupling quantity Trk2.

In the case of transmission systems with an adaptive equaliser 7, which works with the symbol rate (so-called “T-spaced equaliser”), the situation of the sampling time point has a great influence on the equaliser error and therefore on the noise characteristics of the transmission system. The optimum sampling phase in this case is dependent on the transmission channel, in the case of a cable-based transmission system, for example, on the length of the cable. For the optimum sampling phase, optimum equaliser coefficients result. The de-coupling quantity Trk2 by the device 9, which serves to develop the control of the sampling timing by the adaptive equaliser 7, can now be generated in such a way that the optimum equaliser coefficients are adjusted and therefore the optimum sampling phase results. This will be explained in detail below on the basis of a device according to the invention for a transmission system with pulse amplitude modulation (PAM), for example in the form of a SDSL transmission system (“Single Pair of Symmetric Digital Subscriber Line”), whereby, in this case, a base band transmission system is concerned.

In this case, it is assumed that only the equaliser coefficient before the main coefficient is used by the device 9 shown in FIG. 1 for de-coupling the sampling timing control from the adaptive equaliser 7. The device 9 calculates the de-coupling quantity Trk2 according to the following equation:

Trk2(k)=K×(C₋₁(k)−C₋₁(ref))

In this case, the value k designates the symbol or sampling time point, K designates a real scaling factor, for example K=2^{L} where L is a whole number by which the transient recovery characteristics of the timing control loop can be influenced, C₋₁ (k) designates the equaliser coefficients before the main coefficient of the adaptive equaliser 7, and C₋₁ (ref) designates a reference value which can be pre-set. In the transient recovered state, the value of C₋₁ (k) will be adjusted according to this reference value.

The equaliser coefficient C₋₁ (k) observed lies in the case of the optimum sampling phase, in each case according to the cable length related to the main coefficient roughly in the range of 0.05 . . . 0.3. With the aid of a secondary criterion, which, for example, is derived from the digital AGC (Automatic Gain Control) value of the digital receiver, an appropriate reference value C₋₁ (ref) can be generated for each transmission cable selected.

A corresponding arrangement is shown in FIG. 2.

As is clear from FIG. 2, an appropriate reference value C₋₁ (ref) is produced with the aid of a device 12 in dependence on the digital AGC value of the digital receiver arrangement.

A subtracter 13 forms the difference between the equaliser coefficient C₋₁ (k) and the reference coefficient C₋₁ (ref). The output signal of the subtracter 13 is multiplied in a multiplier 14 with the real scaling factor K=2^{L} (L is a whole number), which can be carried out through a simple bit-shift operation of the digital output value of the subtracter 13 by L bit position. The output value of the multiplier 14 is then fed as de-coupling quantity Trk2 to the adder 11.

As already mentioned, the portion Trk1 of the timing control criterion is calculated from the signal values before and after the decision element 8. Favourable jitter characteristics result, in particular, if the portion Trk1 is calculated according to the following equation:

Trk1(k)=Δy(k)×a(k−1)−Δy(k−1)×a(k)

In this case, k designates the symbol or sampling time point, Δy the decision element error, that is to say the difference between the input value of the decision element 8 and the output value of the decision element 8, and a the output value decided by the decision element. Instead of the values for Δy(k) and a(k) for generating the portion Trk1(k), only the algebraic sign of Δy(k) or a(k) can also be used.

FIG. 3 shows a corresponding arrangement for generating the portion Trk1.

With the aid of a subtracter 16, the difference between the input symbol value y(k) and the output symbol value a(k) decided by the decision element 8 is calculated, whereby the output symbol value a(k) has been previously multiplied with the aid of a multiplier 15 with the decision element threshold of the decision element 8. The value Δy(k) is therefore emitted by the subtracter 16. A device 17 calculates the algebraic sign of this difference value. A time element 19 correspondingly emits the algebraic sign of the difference value Δy(k−1) directly above. Furthermore, a device 18 is provided, which calculates the algebraic sign of the symbol value a(k) decided by the decision element 8. A further time element 20 correspondingly emits the algebraic sign of the symbol value a(k−1) decided directly above. The products sgn (Δy(k))×sgn (a(k−1) and sgn (Δy(k−1))×sgn(a(k)) are calculated with the aid of multipliers 21 and 22. In the adder 11, the two products are subtracted and the result Trk1(k) obtained from this is added to the output value Trk1(k) of the multiplier 14, so that as output signal the timing control criterion Trk(k) sought is finally obtained.

The method described above can also be used, for example, in the case of a QAM or CAP transmission system. Here, the demodulated input signal can be interpreted as a complex signal with real and imaginary part. Consequently, an adaptive equaliser 7 capable of handing such signals is necessary. The first part Trk1 of the timing control criterion can be generated both from the real part of the demodulated input signal as well as from the imaginary part of the demodulated input signal or, however, also from both portions (that is to say the sum of the timing control criteria calculated from the real and imaginary part). For de-coupling, the same arrangement can be used as in FIG. 1-FIG. 3. Advantageously, the coefficient C₋₁(k) of the real part of the complex equaliser 7 is used here for de-coupling.

1. A method for controlling the sampling timing of a digital receiver, whereby the digital receiver (2) comprises an adaptive equaliser (7) for equalizing an input signal and a decision element (8) for determining symbol values of the input signal, and whereby a timing control criterion (Trk) is obtained from the input signal and in dependence on the timing control criterion sampling timing of the digital receiver (2) is controlled, characterised in that a first timing control criterion portion (Trk1) is obtained by evaluating the input signal and the output signal of the decision element (8), wherein a second timing control criterion portion (Trk2) is obtained by evaluating at least one coefficient of the adaptive equaliser (7) and wherein the timing control criterion (Trk) is obtained by combining the first timing control criterion portion (Trk1) and the second timing control criterion portion (Trk2).

2. A method according to claim 1, characterised in that the timing control criterion (Trk) is obtained by adding the first timing control criterion portion (Trk1) and the second timing control criterion portion (Trk2).

3. A method according to claims 1 or 2, characterised in that the first timing control criterion portion (Trk1) is obtained by a subtraction between the input signal and the output signal of the decision element (8).

4. A method according to one of the above claims, characterised in that the individual values of the first timing control criterion portion are determined by the equation
Trk1(k)=Δy(k)×a(k−1)−Δy(k−1)×a(k)
or
Trk1(k)=sgn (Δy(k))×sgn (a(k−1))−sgn (Δy(k−1))×sgn (a(k))
where Δy(k)=y(k)−a(k)
whereby k designates the time point, Trk1(k) the values of the first timing control criterion portion, y(k) the input values of the decision element (8) and a(k) the output values of the decision element (8).

5. A method according to any one of the above claims, characterised in that the second timing control criterion portion (Trk2) is obtained by evaluating maximum two coefficients of the adaptive equaliser (7).

6. A method according to claim 5, characterised in that the second timing control criterion portion (Trk2) is obtained by evaluating the coefficients (C₋₁) before the main coefficient and/or the coefficient after the main coefficient of the adaptive equaliser (7).

7. A method according to claims 5 or 6, characterised in that the second timing control criterion portion (Trk2) is obtained by comparing the evaluated coefficient of the adaptive equaliser (7) with a reference value.

8. A method according to claim 6 and claim 7, characterised in that the individual values of the second timing control criterion portion are obtained according to the following equation:
Trk2(k)=K×(C₋₁(k)−C₋₁(ref)),
whereby k designates the time point, Trk2 (k) the values of the second timing control criterion portion, K a real scaling factor, C₋₁ (k) the coefficient before the main coefficient of the adaptive equaliser (7) and C₋₁ (ref) the reference value.

9. A method according to claim 8, characterised in that, for the real scaling factor, the equation K=2^{L} applies, where L is a whole number.

10. A device for controlling the sampling timing of a digital receiver, whereby the digital receiver (2) comprises an adaptive equaliser (7) for equalizing an input signal and a decision element (8) for determining symbol values of the input signal with a device (3) for obtaining a timing control criterion (Trk) from the input signal, and with a timing control loop (3-6) for producing timing of the digital receiver (2) controlled in dependence on the timing control criterion (Tkr), characterised in that the device (3) for obtaining the timing control criterion (Trk) comprises first means (10) for obtaining a first timing control criterion portion (Trk1) by evaluating the input signal and the first output signal of the decision element (8), wherein the device (3) for obtaining the timing control criterion (Trk) comprises second means (9) for obtaining a second timing control criterion portion (Trk2) by evaluating at least one coefficient of the adaptive equaliser (7), and wherein combination means (11) for obtaining the timing control criterion (Trk) by combining the first timing control criterion portion (Trk1) with the second timing control criterion portion (Trk2) are provided.

11. A device according to claim 10, characterised in that the combination means (11) are configured in the form of an adder.

12. A device according to claims 10 or 11, characterised in that the first means (10) for calculating the individual values of the first timing control criterion portion are configured according to one of the following equations:
Trk1(k)=Δy(k)×a(k−1)−Δy(k−1)×a(k)
or
Trk1(k)=sgn (Δy(k))×sgn (a(k−1))−sgn (Δy(k−1))×sgn (a(k)),
where Δy(k)=y(k)−a(k),
whereby k designates the time point, Trk1(k) the individual values of the first timing control criterion portion, y(k) the input values of the decision element (8) and a(k) the output values of the decision element (8).

13. A device according to any one of claims 10-12, characterised in that the second means (9) for obtaining the second timing control criterion portion (Trk2) are configured by evaluating maximum two coefficients of the adaptive equaliser (8).

14. A device according to claim 13, characterised in that the second means (9) for obtaining the second timing control criterion portion (Trk2) are configured by evaluating the coefficient (C₋₁) before the main coefficient of the adaptive equaliser (7) and/or the coefficient after the main coefficient of the adaptive equaliser (7).

15. A device according to any one of claims 10-14, characterised in that the second means (9) are configured in such a way that they compare at least one coefficient (C₋₁) of the adaptive equaliser (7) with a reference value (C₋₁ (ref)) and in dependence on this determine the second timing control criterion portion (Trk2).

16. A device according to claim 14 and claim 15, characterised in that the second means (9) for calculating the individual values of the second timing control criterion portion are configured according to the following equation:
Trk2(k)=K×(C₋₁(k)−C₋₁(ref)),
whereby k designates the time point, Trk2(k) the individual values of the second timing control criterion portion, K a real scaling factor, C₋₁ (k) the equaliser coefficient before the main coefficient of the adaptive equaliser (7) and C₋₁ (ref) the reference value.

17. A device according to claim 16, characterised in that, for the real scaling factor, the equation
K=2^{L} applies, where L is a whole number.

18. A device according to any one of claims 10-17, characterised in that the decision element (8) is connected after the adaptive equaliser (7).

19. Use of a device according to any one of claims 10-18 for controlling the sampling timing of a digital receiver (2) in a PAM transmission system.

20. Use of a device according to any one of claims 10-18 for controlling the sampling timing of a digital receiver (2) in a transmission system, whereby the input signal is present in the form of a complex signal with a real and an imaginary part, whereby the adaptive equaliser (7) of the digital receiver (2) can handle such signals.

21. Use according to claim 20, characterised in that the first timing control criterion portion (Trk1) is obtained from the real part and/or the imaginary part of the input signal.

22. Use according to claims 20 or 21, characterised in that the second timing control criterion portion (Trk2) is obtained by evaluating at least one coefficient of the real part of the complex significant adaptive equaliser (7) capable of handling such signals.

23. Use according to any one of claims 20-22, characterised in that the transmission system is a QAM or CAP transmission system.
